(19) United States
(12) Patent Application Publication
(10) Pub. No.: US 2024/0060175 A1
(43) Pub. Date: Feb. 22, 2024

(54) CONFORMAL MOLYBDENUM DEPOSITION

(71) Applicant: Applied Materials, Inc., Santa Clara, CA (US)

(72) Inventors: Srinivas Gandikota, Santa Clara, CA (US); Yixiong Yang, Fremont, CA (US); Yong Yang, Boston, MA (US); Tuerxun Ailihumaer, Santa Clara, CA (US); Yogesh Sharma, Sunnyvale, CA (US); Kunal Bhatnagar, Chandler, AZ (US); Mohith Verghese, Phoenix, AZ (US)

(73) Assignee: Applied Materials, Inc., Santa Clara, CA (US)

(21) Appl. No.: 17/891,753

(22) Filed: Aug. 19, 2022

(51) Int. Cl. C23C 16/06; H01L 21/285; C23C 16/455

(52) U.S. Cl. CPC C23C 16/06; H01L 21/28556; C23C 16/45553

(57) ABSTRACT

Embodiments of the disclosure provide conformally deposited molybdenum films having reduced resistivity and methods of forming the same. The methods include forming a nucleation layer directly on a dielectric layer on a substrate surface by exposing the substrate surface to a molybdenum-containing precursor and a nucleation reactant, and conformally depositing a molybdenum film on the nucleation layer. Another aspect of the disclosure pertains to a method that is part of a gap fill process, comprising forming a nucleation layer directly on a dielectric region within one or more high aspect ratio gap features, including vertical gap features and/or horizontal gap features, and conformally depositing a molybdenum film on the nucleation layer to fill the feature.

### TECHNICAL FIELD

Embodiments of the present disclosure pertain to metal film deposition. More particularly, embodiments of the disclosure are directed to conformal molybdenum deposition.

### BACKGROUND

As circuit integration increases, there is an enhanced need for greater uniformity and process control regarding layer thickness. As a result, various technologies have been developed to deposit layers on substrates in a cost-effective manner, while maintaining control over the characteristics of the layer. Chemical vapor deposition (CVD) is one of the most common deposition processes employed for depositing layers on a substrate.

A variant of CVD that demonstrates excellent step coverage is cyclical deposition or atomic layer deposition (ALD). ALD employs chemisorption techniques to deliver precursor molecules on a substrate surface in sequential cycles. An ALD cycle includes exposing the substrate surface to a first precursor, a purge gas, a second precursor, and the purge gas. The first and second precursors react to form a product compound as a film on the substrate surface. The ALD cycle is repeated to form the layer to a desired thickness.

The advancing complexity of advanced microelectronic devices is placing stringent demands on currently used deposition techniques. Molybdenum and molybdenum-based films have attractive material and conductive properties. These films have been proposed and tested for applications from front-end to back-end parts of semiconductor and microelectronic devices.

While not wishing to be bound by any particular theory or principle, it is believed that molybdenum cannot be deposited and grown directly on a dielectric surface, and that molybdenum can be deposited and grown on a metallic surface.

Molybdenum films may be used as low resistivity electrical connections in the form of vertical interconnects and/or horizontal interconnects through which current flows, as vias between adjacent metal layers, and as contacts between a first metal layer and the devices on a substrate. For example, in both blanket films and in gap fill applications, a liner film (e.g., a TiN liner film) is typically deposited on a dielectric surface to achieve repeatable molybdenum deposition. In gap fill applications, TiN is deposited in the gap to achieve both low resistivity and conformal deposition. Conformal deposition is often required in order to uniformly deposit a metal film over three-dimensional structures including high aspect ratio features.

There is an ongoing need for improved metal liners or metal layers to provide lower resistivity of molybdenum films. Accordingly, there is a need for improved materials and methods for depositing metal films on dielectric surfaces to provide conformal molybdenum deposition having improved film properties.

### SUMMARY

One or more embodiments of the disclosure are directed to a deposition method comprising forming a nucleation layer directly on a dielectric layer on a substrate surface by exposing the substrate surface to a molybdenum-containing precursor and a nucleation reactant; and conformally depositing a molybdenum film on the nucleation layer.

Additional embodiments of the disclosure are directed to a method of filling a feature formed on a substrate surface. The method of filling the feature formed on the substrate surface comprises forming a nucleation layer directly on a dielectric region within the feature by exposing the dielectric to a molybdenum-containing precursor and a nucleation reactant. The feature comprises at least one surface defining a via. The via comprises a bottom and two sidewalls comprising the dielectric. The method further comprises conformally depositing a molybdenum film on the nucleation layer to fill the feature, the conformally deposited molybdenum film substantially free of seams and voids.

Further embodiments of the disclosure are directed to a non-transitory computer readable medium including instructions, that, when executed by a controller of a processing chamber, cause the processing chamber to: form a nucleation layer directly on a dielectric layer on a substrate surface by exposing the substrate surface to a molybdenum-containing precursor and a nucleation reactant; and conformally deposit a molybdenum film on the nucleation layer.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments. The embodiments as described herein are illustrated by way of example and not limitation in the figures of the accompanying drawings in which like references indicate similar elements.

FIG. 1 illustrates a process flow diagram of a deposition method according to one or more embodiments;

FIG. 2A illustrates a schematic cross-sectional view of a dielectric layer on a substrate surface according to one or more embodiments;

FIG. 2B illustrates a schematic cross-sectional view of a nucleation layer on the dielectric layer on the substrate surface shown in FIG. 2A according to one or more embodiments;

FIG. 2C illustrates a schematic cross-sectional view of a metal film on the nucleation layer shown in FIG. 2B according to one or more embodiments;

FIG. 3A illustrates a schematic cross-sectional view of a feature on a substrate according to one or more embodiments;

FIG. 3B illustrates a schematic cross-sectional view of a nucleation layer on a dielectric region of the feature on the substrate shown in FIG. 3A according to one or more embodiments; and

FIG. 3C illustrates a schematic cross-sectional view of a conformally deposited metal film on the nucleation layer shown in FIG. 3B according to one or more embodiments.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

The term “about” as used herein means approximately or nearly and in the context of a numerical value or range set forth means a variation of ±15%, or less, of the numerical value. For example, a value differing by ±14%, ±10%, ±5%, ±2%, or ±1%, would satisfy the definition of about.

As used in this specification and the appended claims, the term “substrate” or “wafer” refers to a surface, or portion of a surface, upon which a process acts. It will also be understood by those skilled in the art that reference to a substrate can refer to only a portion of the substrate, unless the context clearly indicates otherwise. Additionally, reference to depositing on a substrate can mean both a bare substrate and a substrate with one or more films or features deposited or formed thereon.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, and any other materials such as metals, metal nitrides, metal alloys, and other conductive materials, depending on the application. In some embodiments, the substrate includes one or more of titanium nitride (TiN), titanium silicide (TiSi), a tungsten-titanium silicide alloy, cleaned silicon (Si), boron-doped silicon germanium (SiGeB), cleaned silicon phosphorous (SiP), titanium aluminum (TiAl), ruthenium (Ru), tungsten (W), and molybdenum (Mo). Substrates include, without limitation, semiconductor wafers.

Substrates may be exposed to a pretreatment process to polish, etch, reduce, oxidize, hydroxylate, anneal and/or bake the substrate surface. In addition to film processing directly on the surface of the substrate itself, in the present disclosure, any of the film processing steps disclosed may also be performed on an under-layer formed on the substrate as disclosed in more detail below, and the term “substrate surface” is intended to include such under-layer as the context indicates. Thus, for example, where a film/layer or partial film/layer has been deposited onto a substrate surface, the exposed surface of the newly deposited film/layer becomes the substrate surface.

As used herein, the term “substrate surface” refers to any substrate surface upon which a layer may be formed. The substrate surface may have one or more features formed therein, one or more layers formed thereon, and combinations thereof. The shape of the feature can be any suitable shape including, but not limited to, peaks, trenches, and cylindrical vias. As used in this regard, the term “feature” refers to any intentional surface irregularity. Suitable examples of features include but are not limited to trenches which have a top, two sidewalls and a bottom, peaks which have a top and two sidewalls extending upward from a surface, and vias which have sidewalls extending down from a surface with a bottom. In some embodiments, the bottom of a via comprises an open bottom defined or bounded by underlying material, for example, dielectric material, which may also define the two sidewalls, or the underlying material at the bottom may be a conductor such as a metal (e.g., copper), which can be the same as or different from the sidewall material.

As used in this specification and the appended claims, the term “selectively” refers to process which acts on a first surface with a greater effect than another second surface. Such a process would be described as acting “selectively” on the first surface over the second surface. The term “over” used in this regard does not imply a physical orientation of one surface on top of another surface, rather a relationship of the thermodynamic or kinetic properties of the chemical reaction with one surface relative to the other surface.

The term “on” indicates that there is direct contact between elements. The term “directly on” indicates that there is direct contact between elements with no intervening elements.

As used in this specification and the appended claims, the terms “precursor”, “reactant”, “reactive gas” and the like are used interchangeably to refer to any gaseous species that can react with the substrate surface.

“Atomic layer deposition” or “cyclical deposition” as used herein refers to the sequential exposure of two or more reactive compounds to deposit a layer of material on a substrate surface. The substrate, or portion of the substrate, is exposed separately to the two or more reactive compounds which are introduced into a reaction zone of a processing chamber. In a time-domain ALD process, exposure to each reactive compound is separated by a time delay to allow each compound to adhere and/or react on the substrate surface and then be purged from the processing chamber. These reactive compounds are said to be exposed to the substrate sequentially. In a spatial ALD process, different portions of the substrate surface, or material on the substrate surface, are exposed simultaneously to the two or more reactive compounds so that any given point on the substrate is substantially not exposed to more than one reactive compound simultaneously. As used in this specification and the appended claims, the term “substantially” used in this respect means, as will be understood by those skilled in the art, that there is the possibility that a small portion of the substrate may be exposed to multiple reactive gases simultaneously due to diffusion, and that the simultaneous exposure is unintended.

In one aspect of a time-domain ALD process, a first reactive gas (i.e., a first precursor or compound A) is pulsed into the reaction zone followed by a first time delay. Next, a second precursor or compound B is pulsed into the reaction zone followed by a second delay. During each time delay, a purge gas, such as argon, is introduced into the processing chamber to purge the reaction zone or otherwise remove any residual reactive compound or reaction by-products from the reaction zone. Alternatively, the purge gas may flow continuously throughout the deposition process so that only the purge gas flows during the time delay between pulses of reactive compounds. The reactive compounds are alternatively pulsed until a desired film or film thickness is formed on the substrate surface. In either scenario, the ALD process of pulsing compound A, purge gas, compound B and purge gas is a cycle. A cycle can start with either compound A or compound B and continue the respective order of the cycle until achieving a film with the predetermined thickness.

In an embodiment of a spatial ALD process, a first reactive gas and second reactive gas (e.g., nitrogen gas) are delivered simultaneously to the reaction zone but are separated by an inert gas curtain and/or a vacuum curtain. The substrate is moved relative to the gas delivery apparatus so that any given point on the substrate is exposed to the first reactive gas and the second reactive gas.

Embodiments of the disclosure advantageously provide methods which improve blanket molybdenum film resistivity deposited on an underlying molybdenum layer formed by the methods described in this disclosure.

Resistivity is an intrinsic property of a material and a measurement of a material's resistance to the movement of charge through the material. The resistivity of a material affects the electrical operation of an integrated circuit. Low resistivity molybdenum films minimize power losses and overheating in integrated circuit designs. Because the resistivity of the nucleation layer is typically greater than the resistivity of the bulk material, the thickness of the nucleation layer should be minimized to keep the total resistance as low as possible. On the other hand, the molybdenum nucleation layer should be sufficiently thick to fully cover the underlying substrate to support high quality bulk deposition. For narrow width and/or high aspect ratio and thin features, obtaining thin nucleation layers is even more critical.

In addition to providing molybdenum-containing films having low resistivity, the methods described herein provide films having good uniformity and adhesion to the underlying material. One or more embodiments provides methods in which a molybdenum nucleation layer is deposited directly on a dielectric surface. The inventors have surprisingly found that a unique combination of molybdenum-containing precursors and nucleation reactants allows for molybdenum deposition on a dielectric surface. Further embodiments advantageously provide methods of reducing the stack resistivity of bottom-up gap fill for vias with improved molybdenum film properties.

The embodiments of the disclosure are described by way of the Figures, which illustrate devices (e.g., transistors) and processes for forming transistors in accordance with one or more embodiments of the disclosure. The processes shown are merely illustrative possible uses for the disclosed processes, and the skilled artisan will recognize that the disclosed processes are not limited to the illustrated applications.

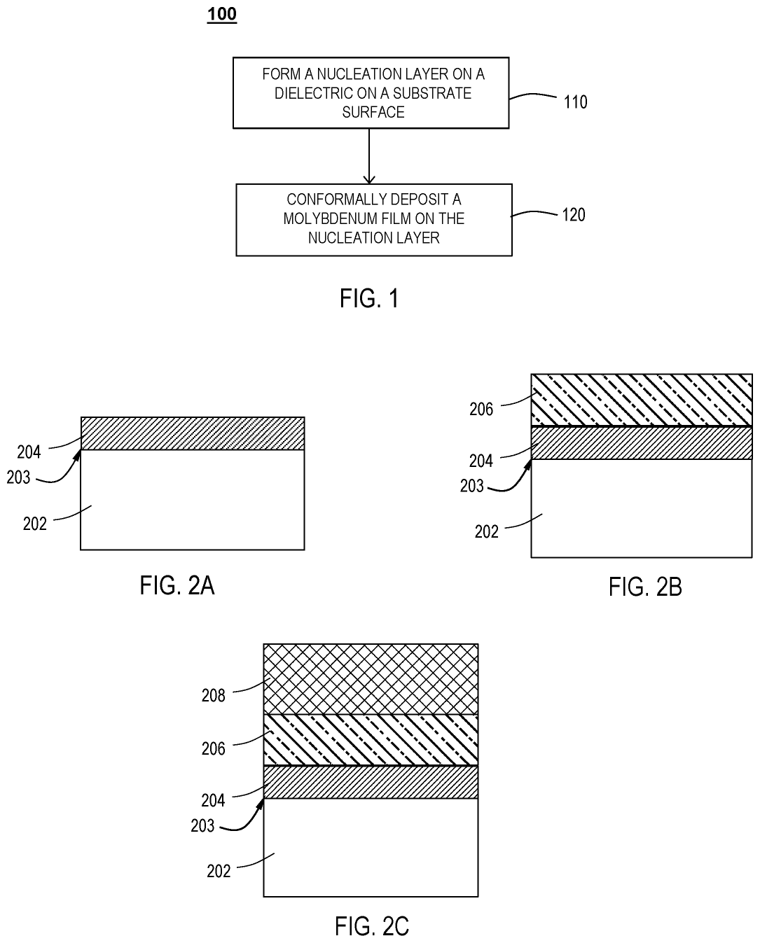

FIG. 1 depicts a process flow diagram of a deposition method 100 in accordance with one or more embodiments of the present disclosure. The deposition method 100, at operation 110, comprises forming a nucleation layer directly on a dielectric surface, for example, on a dielectric layer on a substrate, or on a dielectric region of a substrate. In some embodiments, at operation 110, forming the nucleation layer directly on the dielectric surface comprises exposing the substrate surface to a molybdenum-containing precursor and a nucleation reactant. In general, a nucleation layer is a thin conformal layer which serves to facilitate the subsequent formation of a bulk material thereon. As used herein, the term “nucleation layer” refers to a layer deposited on a dielectric surface that allows the formation of a bulk material thereon (e.g., a molybdenum-containing film). In some embodiments, the nucleation reactant is different than a molybdenum film reactant.

In some embodiments, at operation 110, forming the nucleation layer comprises one or more of atomic layer deposition (ALD), co-flowing the molybdenum-containing precursor and the nucleation reactant, chemical vapor deposition (CVD), or pulsed chemical vapor deposition (pCVD).

In some embodiments, at operation 110, forming the nucleation layer comprises atomic layer deposition (ALD), which includes one or more cycles of exposing the substrate surface to a first precursor (e.g., the molybdenum-containing precursor), a purge gas, a second precursor (e.g., the nucleation reactant), and the purge gas.

In some embodiments, at operation 110, forming the nucleation layer comprises a spatial ALD process, wherein a first reactive gas (e.g., the molybdenum-containing precursor) and second reactive gas (e.g., the nucleation reactant) are delivered simultaneously to the reaction zone but are separated by an inert gas curtain and/or a vacuum curtain. In some embodiments, at operation 110, forming the nucleation layer comprises co-flowing the molybdenum-containing precursor and the nucleation reactant. In some embodiments, at operation 110, forming the nucleation layer comprises chemical vapor deposition (CVD). In some embodiments, at operation 110, forming the nucleation layer comprises pulsed chemical vapor deposition (pCVD), wherein one or both of the reactants is pulsed into a chamber.

In some embodiments, the molybdenum-containing precursor comprises one or more of molybdenum pentachloride (MoCl₅), molybdenum dioxide dichloride (MoO₂Cl₂), molybdenum oxytetrachloride (MoOCl₄), or molybdenum hexafluoride (MoF₆).

In some embodiments, the nucleation reactant comprises one or more of silane (SiH₄), disilane (Si₂H₆), or diborane (B₂H₆).

In one or more embodiments, at operation 110, forming the nucleation layer directly on the dielectric surface is performed at a temperature in a range of 300° C. to 700° C., for example at a temperature in a range of from 300° C. to 650° C., in a range of from 300° C. to 600° C., in a range of from 300° C. to 550° C. or in a range of from 300° C. to 500° C. and at a pressure in a range of from 1 Torr to 300 Torr, for example at a pressure in a range of from 10 Torr to 250 Torr or in a range of from 10 Torr to 200 Torr.

The deposition method 100 comprises, at operation 120, conformally depositing a molybdenum film on the nucleation layer. In some embodiments, at operation 120, conformally depositing the molybdenum film comprises exposing the nucleation layer to the molybdenum-containing precursor and a molybdenum film reactant that is different from the nucleation reactant. In some embodiments, the molybdenum-containing precursor comprises one or more of molybdenum pentachloride (MoCl₅), molybdenum dioxide dichloride (MoO₂Cl₂), molybdenum oxytetrachloride (MoOCl₄), or molybdenum hexafluoride (MoF₆). In some embodiments, the molybdenum film reactant comprises hydrogen (H₂).

In one or more embodiments, at operation 120, conformally depositing the molybdenum film comprises one or more of atomic layer deposition (ALD), co-flowing a molybdenum-containing precursor and hydrogen (H₂), chemical vapor deposition (CVD), or pulsed chemical vapor deposition (pCVD). In some embodiments, at operation 120, conformally depositing the molybdenum film comprises atomic layer deposition (ALD), which includes one or more cycles of exposing the substrate surface to a first precursor (e.g., the molybdenum-containing precursor), a purge gas, a second precursor (e.g., the molybdenum film reactant), and the purge gas.

In some embodiments, at operation 120, conformally depositing the molybdenum film comprises a spatial ALD process, wherein a first reactive gas (e.g., the molybdenum-containing precursor) and second reactive gas (e.g., the molybdenum film reactant) are delivered simultaneously to the reaction zone but are separated by an inert gas curtain and/or a vacuum curtain. In some embodiments, at operation 120, conformally depositing the molybdenum film comprises co-flowing the molybdenum-containing precursor and hydrogen (H₂). In some embodiments, at operation 120, conformally depositing the molybdenum film comprises chemical vapor deposition (CVD). In some embodiments, at operation 120, conformally depositing the molybdenum film comprises pulsed chemical vapor deposition (pCVD), wherein one or both of the reactants is pulsed into a chamber.

In some embodiments, conformally depositing the molybdenum film is performed at a temperature in a range of 300° C. to 700° C., for example at a temperature in a range of from 300° C. to 650° C., in a range of from 300° C. to 600° C., in a range of from 300° C. to 550° C. or in a range of from 300° C. to 500° C. and at a pressure in a range of from 1 Torr to 300 Torr, for example at a pressure in a range of from 10 Torr to 250 Torr or in a range of from 10 Torr to 200 Torr.

FIGS. 2A-2C depict cross-sectional views of a deposition process on a substrate according to one or more embodiments which produces low electrical resistivity films on a dielectric layer. Referring first to FIG. 2A, a substrate 202 is shown, having a surface such as top surface 203 and a dielectric layer 204 on the top surface 203. Referring to FIG. 2B, in a one or more embodiments, the deposition method 100 comprises forming a nucleation layer 206 directly on the dielectric layer 204 on the top surface 203 of the substrate 202. Referring to FIG. 2C, in one or more embodiments, the deposition method 100 comprises conformally depositing a molybdenum film 208 on the nucleation layer 206.

The substrate 202 can be any suitable substrate material. In one or more embodiments, the substrate 202 comprises a semiconductor material, e.g., silicon (Si), carbon (C), germanium (Ge), silicon germanium (SiGe), gallium arsenide (GaAs), indium phosphate (InP), indium gallium arsenide (InGaAs), indium aluminum arsenide (InAlAs), germanium (Ge), silicon germanium (SiGe), other semiconductor materials, or any combination thereof. In one or more embodiments, the substrate 400 comprises one or more of silicon (Si), germanium (Ge), gallium (Ga), arsenic (As), indium (In), phosphorus (P), or selenium (Se). In some embodiments, the substrate 202 comprises one or more of titanium nitride (TiN), titanium silicide (TiSi), a tungsten-titanium silicide alloy, cleaned silicon (Si), boron-doped silicon germanium (SiGeB), cleaned silicon phosphorous (SiP), titanium aluminum (TiAl), ruthenium (Ru), tungsten (W), and molybdenum (Mo). Although a few examples of materials from which the substrate 202 may be made have been provided, any material that may serve as a foundation upon which passive and active electronic devices (e.g., transistors, memories, capacitors, inductors, resistors, switches, integrated circuits, amplifiers, optoelectronic devices, or any other electronic devices) may can be utilized.

In some embodiments, the substrate 202 may include dielectric materials, for example, silicon-containing dielectric materials and/or metal oxide dielectric materials. In some embodiments, the substrate 202 may comprise one or more dielectric surfaces (such as dielectric layer 204) comprising a dielectric material such as, but not limited to, silicon oxide (SiOₓ), silicon sub-oxides, silicon nitride (SiNₓ), silicon carbide (SiCₓ), silicon carbonitride (SiCₓN_{y}), silicon oxynitride (SiOₓN_{y}), tantalum nitride (TaN), hafnium oxide (HfOₓ), a low-K dielectric material, or combinations thereof.

The nucleation layer 206 may have any suitable thickness. In some embodiments, the nucleation layer 206 has a thickness of less than or equal to 10 Å, including, for example, a thickness in a range of from 0.5 Å to 10 Å, 1 Å to 9 Å, 2 Å to 8 Å, 3 Å to 8 Å, 4 Å to 7 Å, or 5 Å to 6 Å.

Advantageously, the conformally deposited molybdenum film 208 on the nucleation layer 206 has a resistivity that is reduced by at least 30% compared to a titanium nitride (TiN) film having a conformally deposited molybdenum film deposited thereon. In some embodiments, the nucleation layer 206 and the conformally deposited molybdenum film 208 define a film stack having a resistivity less than or equal to 35 μΩ-cm when the nucleation layer 206 and the conformally deposited molybdenum film 208 have a combined thickness of about 100 Å. In some embodiments, the resistivity of the film stack when the nucleation layer 206 and the conformally deposited molybdenum film 208 have a combined thickness of about 100 Å is in a range of from 20 μΩ-cm to 35 μΩ-cm, including in a range of from 25 μΩ-cm to 35 μΩ-cm, in a range of from 20 μΩ-cm to 25 μΩ-cm, or in a range of from 30 μΩ-cm to 35 μΩ-cm. In some embodiments, the resistivity of the film stack when the nucleation layer 206 and the conformally deposited molybdenum film 208 have a combined thickness of about 100 Å is about 31 μΩ-cm.

Another aspect of the disclosure pertains to a method that is part of a gap fill process. Thus, a molybdenum metal film is deposited on a dielectric surface with one or more high aspect ratio gap features, including vertical gap features and/or horizontal gap features, the molybdenum in the gap features forming horizontal interconnects through which current flows. Without intending to be bound by theory, gaps filled with molybdenum conformally deposited on the nucleation layer, according to one or more embodiments of methods described herein, results in improved electrical operation of an integrated circuit, by minimizing power losses and overheating in the integrated circuit having molybdenum-filled gaps.

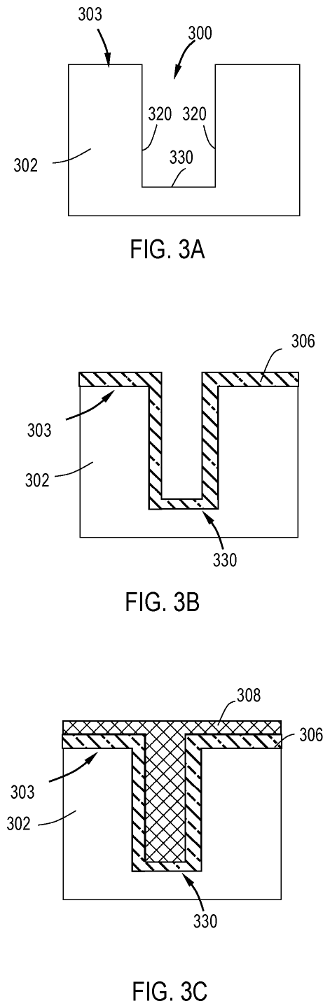

Referring to FIGS. 3A-3C, a method of filling a feature formed on a top surface 303 of a substrate 302 is shown with respect to a feature 300 that has a gap defined by opposed sidewalls 320 and a bottom 330. The substrate 302 can comprise any of the non-limiting materials described above with respect to FIGS. 2A-2C. In the embodiments shown in FIGS. 3A-3C, the substrate 302 comprises a dielectric region.

In one of more embodiments, referring to FIG. 3B, a method of filing the feature comprises forming a nucleation layer 306 directly on a dielectric region including a top surface 303 within the feature 300 on the surface of the substrate 302, the feature 300 comprising at least one surface defining a via, the via comprising a bottom 330 and two opposed sidewalls 320 comprising the dielectric.

Referring to FIG. 3C, the method comprises conformally depositing a molybdenum film 308 on the nucleation layer 306 to fill the feature 300, the conformally deposited molybdenum film 310 substantially free of seams or voids.

The Figures show a substrate 302 having a single feature 300 for illustrative purposes; however, those skilled in the art will understand that there can be more than one feature 300. The shape of the feature 300 can be any suitable shape including, but not limited to, trenches and cylindrical vias. As used in this regard, the term “feature” means any intentional surface irregularity. Suitable examples of features include, but are not limited to, trenches which have a top, two sidewalls and a bottom, peaks which have a top and two sidewalls extending upward from a surface, and vias which have sidewalls extending down from a surface with a bottom. In some embodiments, the bottom of a via comprises an open bottom defined or bounded by underlying material, for example, dielectric material, which may also define the two sidewalls, or the underlying material at the bottom may be a conductor such as a metal (e.g., copper), which may be different material. In one or more embodiments, the at least one feature 300 comprises one or more of a trench or a via. In specific embodiments, the at least one feature 300 comprises a via. In still further embodiments, the term “at least one feature 300” and “via 300” may be used interchangeably. The via 300 has a depth to the bottom 330 and a width between the two opposed sidewalls 320. In some embodiments, the depth is in a range of 2 nm to 200 nm, 3 nm to 200 nm, 5 nm to 100 nm, 2 nm to 100 nm, or 50 nm to 100 nm. In some embodiments, the width is in a range of 10 nm to 100 nm, 10 nm to 20 nm, 10 nm to 50 nm, or 50 nm to 100 nm. In some embodiments, the via 300 has an aspect ratio (depth/width) in a range of 1:1 to 20:1, 5:1 to 20:1, 10:1 to 20:1, or 15:1 to 20:1.

In some embodiments, the operations of deposition method 100 are each performed within the same processing chamber. In some embodiments, the operations of deposition method 100 are each performed within a different processing chamber. In some embodiments, the different processing chambers are connected as part of a processing system. In some embodiments, the operations of deposition method 100 are performed without an intervening vacuum break.

In some embodiments, one or more of the operations of deposition method 100 is performed in situ without breaking vacuum. In some embodiments, one or more of the operations of deposition method is performed ex situ. As used herein, the term “in situ” refers to operations of deposition method 100 that are each performed in the same processing chamber or a different processing chamber that is connected as part of a processing system, such that each of the operations of deposition method 100 are performed without an intervening vacuum break. As used herein, the term “ex situ” refers to operations of deposition method 100 that are each performed in the same processing chamber or a different processing chamber such that one or more of the operations of deposition method 100 are performed with an intervening vacuum break.

In some embodiments, the molybdenum film 308 is laterally bounded by the two opposed sidewalls 320 of the at least one feature 300. As used in this regard, “laterally bounded” means that the deposited material does not extend beyond the point of intersection between the top surface 303 and the two opposed sidewalls 320. In some embodiments, the molybdenum film 308 extends above the at least one feature 300. In some embodiments, the molybdenum film 308 fills the via 300. As used in this regard, a film which “fills the via” has a volume which occupies at least 95%, at least 98%, or at least 99% of the volume of the via 300. In some embodiments, the film which fills the via has a fill height in a range of from 30 nm to 75 nm, including in a range of from 40 nm to 60 nm.

Embodiments of the disclosure advantageously provide molybdenum films 308 having reduced resistivity compared to molybdenum films deposited by processes other than those described herein (e.g., deposition method 100). Embodiments of the disclosure advantageously provides molybdenum films 308 that are free or substantially free of voids and seams. As used in this regard, “substantially free” means that less than about 5%, including less than about 4%, less than about 3%, less than about 2%, less than about 1%, less than about 0.5%, and less than about 0.1% of the total composition of the conformally deposited molybdenum film 308, on an atomic basis, comprises voids and/or seams.

One or more embodiments of the disclosure are directed to a non-transitory computer readable medium including instructions, that, when executed by a controller of a processing chamber, cause the processing chamber to perform the operations of deposition method 100. In some embodiments, the non-transitory computer readable medium includes instructions, that, when executed by a controller of a processing chamber, cause the processing chamber to: form a nucleation layer directly on a dielectric layer on a substrate surface by exposing the substrate surface to a molybdenum-containing precursor and a nucleation reactant (operation 110); and conformally deposit a molybdenum film on the nucleation layer (operation 120).

The disclosure is now described with reference to the following examples. Before describing several exemplary embodiments of the disclosure, it is to be understood that the disclosure is not limited to the details of construction or process steps set forth in the following description. The disclosure is capable of other embodiments and of being practiced or being carried out in various ways.

### EXAMPLES

### Comparative Example 1: Depositing a Molybdenum Film on a Metallic Surface

General procedure: A substrate is placed in a processing chamber. A molybdenum-containing precursor selected from one or more of molybdenum pentachloride (MoCl₅), molybdenum dioxide dichloride (MoO₂Cl₂), molybdenum oxytetrachloride (MoOCl₄), or molybdenum hexafluoride (MoF₆) is flowed into the processing chamber over the substrate leaving a molybdenum-precursor terminated surface. Unreacted precursor and byproducts are then purged out of the processing chamber. Next, a co-reactant comprising hydrogen (H₂) is then introduced into the chamber that reacts with the surface bound molybdenum species. Again, excess co-reactant and byproducts are removed from the chamber. The resultant material on the substrate is a molybdenum-containing film.

The general procedure was repeated until a predetermined thickness of the molybdenum-containing film was reached. In some embodiments, the predetermined thickness was about 100 Å. The molybdenum-containing film was deposited on a variety of substrate materials, including, but not limited to, titanium nitride (TiN), titanium silicide (TiSi), a tungsten-titanium silicide alloy, cleaned silicon (Si), boron-doped silicon germanium (SiGeB), cleaned silicon phosphorous (SiP), titanium aluminum (TiAl), ruthenium (Ru), tungsten (W), and molybdenum (Mo).

When the above general procedure was utilized to in attempt to deposit a molybdenum-containing film on a dielectric surface, including, but not limited to, tantalum nitride (TaN), uncleaned silicon (Si), oxide (Ox), silicon nitride (SiN), or hafnium oxide (HfOx), a molybdenum-containing film was not formed on any of these dielectric surfaces.

### Example 2: Depositing a Molybdenum Film on a Dielectric Surface

General procedure: A substrate is placed in a processing chamber. A molybdenum-containing precursor selected from one or more of molybdenum pentachloride (MoCl₅), molybdenum dioxide dichloride (MoO₂Cl₂), molybdenum oxytetrachloride (MoOCl₄), or molybdenum hexafluoride (MoF₆) is flowed into the processing chamber over the substrate leaving a molybdenum-precursor terminated surface directly on the dielectric surface. The dielectric surfaces utilized include, but are not limited to, tantalum nitride (TaN), uncleaned silicon (Si), oxide (Ox), silicon nitride (SiN), or hafnium oxide (HfOx). Unreacted precursor and byproducts are then purged out of the chamber. Next, a co-reactant comprising one or more of silane (SiH₄), disilane (Si₂H₆), or diborane (B₂H₆) is then introduced into the chamber that reacts with the surface bound molybdenum species. Again, excess co-reactant and byproducts are removed from the processing chamber. The resultant material on the dielectric surface of the substrate is a molybdenum-containing nucleation layer.

Thereafter, a molybdenum-containing precursor selected from one or more of molybdenum pentachloride (MoCl₅), molybdenum dioxide dichloride (MoO₂Cl₂), molybdenum oxytetrachloride (MoOCl₄), or molybdenum hexafluoride (MoF₆) is flowed into the processing chamber over the molybdenum-containing nucleation layer on the dielectric surface of the substrate, leaving a molybdenum-precursor terminated surface directly on the molybdenum-containing nucleation layer. Unreacted precursor and byproducts are then purged out of the chamber. Next, a co-reactant comprising hydrogen (H₂) is then introduced into the chamber that reacts with the surface bound molybdenum species (e.g., the molybdenum-containing nucleation layer). Again, excess co-reactant and byproducts are removed from the processing chamber. The resultant material on the molybdenum-containing nucleation layer is a molybdenum-containing film.

The general procedure was repeated until a predetermined combined thickness of the molybdenum-containing nucleation layer and the molybdenum-containing film was reached. In some embodiments, the predetermined combined thickness was about 100 Å. A molybdenum-containing nucleation layer was formed on each of the above dielectric surfaces (tantalum nitride (TaN), uncleaned silicon (Si), oxide (Ox), silicon nitride (SiN), or hafnium oxide (HfOx)). The general procedure was repeated to grow a molybdenum-containing film on the dielectric surface.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. In one or more embodiments, the particular features, structures, materials, or characteristics are combined in any suitable manner.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

1. A deposition method comprising:
forming a nucleation layer directly on a dielectric layer on a substrate surface by exposing the substrate surface to a molybdenum-containing precursor and a nucleation reactant, forming the nucleation layer comprising one or more of co-flowing the molybdenum-containing precursor and the nucleation reactant, chemical vapor deposition (CVD), or pulsed chemical vapor deposition (pCVD); and
conformally depositing a molybdenum film on the nucleation layer, wherein conformally depositing the molybdenum film comprises exposing the nucleation layer to the molybdenum-containing precursor and a molybdenum film reactant that is different from the nucleation reactant.

2. The deposition method of claim 1, wherein the molybdenum-containing precursor comprises one or more of molybdenum pentachloride (MoCl₅), molybdenum dioxide dichloride (MoO₂Cl₂), molybdenum oxytetrachloride (MoOCl₄), or molybdenum hexafluoride (MoF₆).

3. The deposition method of claim 1, wherein the nucleation reactant comprises one or more of silane (SiH₄), disilane (Si₂H₆), or diborane (B₂H₆).

4. The deposition method of claim 1, wherein forming the nucleation layer is performed at a temperature in a range of 300° C. to 700° C. and at a pressure in a range of from 1 Torr to 300 Torr.

5. (canceled)

6. (canceled)

7. The deposition method of claim 1, wherein conformally depositing the molybdenum film comprises one or more of atomic layer deposition (ALD), co-flowing the molybdenum-containing precursor and the molybdenum film reactant, chemical vapor deposition (CVD), or pulsed chemical vapor deposition (pCVD).

8. The deposition method of claim 1, wherein the molybdenum film reactant comprises hydrogen (H₂).

9. The deposition method of claim 1, wherein the nucleation layer has a thickness of less than or equal to 10 Å.

10. The deposition method of claim 1, wherein the nucleation layer and the conformally deposited molybdenum film define a film stack having a resistivity less than or equal to 35 μΩ-cm when the nucleation layer and the conformally deposited molybdenum film have a combined thickness of about 100 Å.

11. A method of filling a feature formed on a substrate surface, the method comprising:
forming a nucleation layer directly on a dielectric region within the feature by exposing the dielectric to a molybdenum-containing precursor and a nucleation reactant, the feature comprising at least one surface defining a via, the via comprising a bottom and two sidewalls comprising the dielectric, forming the nucleation layer comprising one or more of co-flowing the molybdenum-containing precursor and the nucleation reactant, chemical vapor deposition (CVD), or pulsed chemical vapor deposition (pCVD); and
conformally depositing a molybdenum film on the nucleation layer to fill the feature, wherein conformally depositing the molybdenum film comprises exposing the nucleation layer to the molybdenum-containing precursor and a molybdenum film reactant that is different from the nucleation reactant, and the conformally deposited molybdenum film is substantially free of seams and voids.

12. The method of claim 11, wherein the dielectric comprises silicon oxide (SiOₓ), silicon nitride (SiNₓ), silicon carbide (SiCₓ), silicon carbonitride (SiCₓN_{y}), silicon oxynitride (SiOₓN_{y}), a low-K dielectric material, or combinations thereof.

13. The method of claim 11, wherein the molybdenum-containing precursor comprises one or more of molybdenum pentachloride (MoCl₅), molybdenum dioxide dichloride (MoO₂Cl₂), molybdenum oxytetrachloride (MoOCl₄), or molybdenum hexafluoride (MoF₆).

14. The method of claim 11, wherein the nucleation reactant comprises one or more of silane (SiH₄), disilane (Si₂H₆), or diborane (B₂H₆).

15. The method of claim 11, wherein forming the nucleation layer is performed at a temperature in a range of 300° C. to 700° C. and at a pressure in a range of from 1 Torr to 300 Torr.

16. (canceled)

17. (canceled)

18. The method of claim 11, wherein conformally depositing the molybdenum film comprises one or more of atomic layer deposition (ALD), co-flowing the molybdenum-containing precursor and the molybdenum film reactant, chemical vapor deposition (CVD), or pulsed chemical vapor deposition (pCVD).

19. The method of claim 11, wherein the nucleation layer and the conformally deposited molybdenum film define a film stack having a resistivity less than or equal to 35 μΩ-cm when the nucleation layer and the conformally deposited molybdenum film have a combined thickness of about 100 Å.

20. A non-transitory computer readable medium including instructions, that, when executed by a controller of a processing chamber, cause the processing chamber to:
form a nucleation layer directly on a dielectric layer on a substrate surface by exposing the substrate surface to a molybdenum-containing precursor and a nucleation reactant, forming the nucleation layer comprising one or more of co-flowing the molybdenum-containing precursor and the nucleation reactant, chemical vapor deposition (CVD), or pulsed chemical vapor deposition (pCVD); and
conformally deposit a molybdenum film on the nucleation layer, wherein conformally depositing the molybdenum film comprises exposing the nucleation layer to the molybdenum-containing precursor and a molybdenum film reactant that is different from the nucleation reactant.
